(19) United States
(12) Patent Application Publication
(10) Pub. No.: US 2017/0307691 A1
(43) Pub. Date: Oct. 26, 2017

(54) Intelligent Charge Stop

(71) Applicant: Hilti Aktiengesellschaft, Schaan (LI)

(72) Inventor: Stefan Mayer, Dachau (DE)

(73) Assignee: Hilti Aktiengesellschaft, Schaan (LI)

(21) Appl. No.: 15/513,134

(22) PCT Filed: Sep. 23, 2015
(86) PCT No.: PCT/EP2015/071816

§ 371 Date: Mar. 21, 2017

(30) Foreign Application Priority Data
Sep. 23, 2014 (EP) 14185881.1

(51) Int. Cl. G01R 31/36; H01M 10/42; H01M 10/44; H02J 7/00; H01M 10/48

(52) U.S. Cl. CPC G01R 31/3634; H02J 7/0068; H01M 10/48; H01M 10/4257; H01M 10/44; H01M 2010/4271

(57) ABSTRACT

A method for controlling an accumulator, the accumulator containing a control device and being able to be used, for example, to supply electric power to a machine tool, is disclosed. In an embodiment, the method includes determining a difference value between a first accumulator charging state and a second accumulator charging state, where the first charging state corresponds to an accumulator charging state after a charging process has ended and the second charging state has a charging state value that is lower than the first charging state, determining a third charging state which corresponds to the difference value and corresponds to a charging state value that is lower than a maximum charging state value for the accumulator, and charging the accumulator until the third charging state is reached. An accumulator for carrying out the method is also disclosed.

This application claims the priority of International Application No. PCT/EP2015/071816, filed Sep. 23, 2015, and European Patent Document No. 14185881.1, filed Sep. 23, 2014, the disclosures of which are expressly incorporated by reference herein.

### BACKGROUND AND SUMMARY OF THE INVENTION

The present invention relates to a method for controlling an accumulator, wherein the accumulator comprises a control device and can be used for supplying electrical energy to a machine tool, for example. In addition, the invention relates to an accumulator for executing this method.

Accumulators, particularly lithium-ion accumulators, experience accelerated aging due to a number of environmental influences as well as incorrect handling, where the aging may result in a reduced performance capability and an overall shortened service life of the accumulator. Besides environmental influences, such as excessively high or excessively low ambient temperatures, it is in particular the often improper charging of a battery that represents a problem for performance capability (e.g., output of maximum rated capacity) and the service life of the accumulator.

Therefore, it is the object of the present invention to solve the technical problem described above and in particular to optimize the performance capability of an accumulator as well as to increase the service life of an accumulator. To do so, a method for controlling an accumulator is provided. By means of the method, the performance capability and the service life of the accumulator can be optimized and increased respectively.

To this end a method is provided for controlling an accumulator, wherein the accumulator comprises a control device and can be used to supply a machine tool with electrical energy for example.

The method is characterized according to the invention through the steps:
Determining a difference value between a first charging state of the accumulator and a second charging state of the accumulator, wherein the first charging state corresponds to a charging state of the accumulator after a charging process has ended and the second charging state has a lower charging state value than the first charging state;
Determining a third charging state, which corresponds to the difference value, wherein the third charging state corresponds to a charging state value that is lower than a maximum charging state value of the accumulator; and
Charging the accumulator until the third charging state is reached.

By specifying and charging the accumulator until reaching the third charging state, which is less than a maximum charging state value of the accumulator, one ensures that the accumulator is no longer charged to a maximum charging state. Premature and accelerated aging of the accumulator is hereby counteracted, and the performance capability as well as the service life of the accumulator are optimized.

According to an additional embodiment of the present invention, it may be provided that specifying the third charging state occurs after a predetermined number of accumulator charging processes, wherein the charging state value of the third charging state corresponds to an average difference value. The predetermined number may thereby correspond to at least three charging processes of the accumulator. However, it is also possible that the predetermined number is less than or exactly three charging processes of the accumulator. The third charging state can hereby be set to a charging state value, which corresponds to an actually used or maximum necessary charging state for the accumulator.

To ensure a flexible setting on the third charging state, it may be possible that setting the third charging state to a predetermined first threshold value occurs when the second charging state falls below a predetermined second threshold value.

According to another advantageous embodiment, it may be possible that setting the third charging state occurs by means of an input device positioned at the accumulator. It is hereby possible for a user of the accumulator or a machine tool to freely select the third charging state and to thereby increase or decrease the performance capability of the accumulator as desired.

According to another advantageous embodiment of the present invention, it may be provided that the first, second, and third charging state correspond to a capacity, a charging voltage, or a charging current.

Additional advantages emerge from the following drawing descriptions. The drawings depict various embodiments of the present invention. The drawings, the descriptions, and the claims comprise numerous features in combination. A person skilled in the art will appropriately also consider the features individually and put them together in other reasonable combinations.

### BRIEF DESCRIPTION OF THE DRAWINGS

FIG. 1 is a schematic illustration of a machine tool along with an accumulator according to the invention for carrying out the method according to the invention for controlling the accumulator;

FIG. 2 is a schematic illustration of the accumulator in connection with a charging device;

FIG. 3 is a sequence diagram of the method according to the invention for controlling an accumulator pursuant to a first embodiment;

FIG. 4 is a sequence diagram of the method according to the invention for controlling an accumulator pursuant to a second embodiment;

FIG. 5 is a sequence diagram of the method according to the invention for controlling an accumulator pursuant to a third embodiment; and

FIG. 6 is a sequence diagram of the method according to the invention for controlling an accumulator pursuant to a fourth embodiment.

### DETAILED DESCRIPTION OF THE DRAWINGS

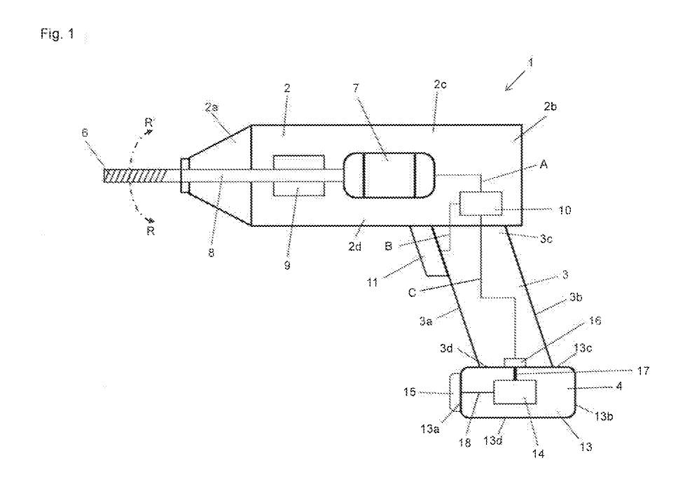

FIG. 1 depicts a machine tool 1 in the form of a drill. Machine tool 1 designed as a drill essentially comprises a housing 2, a grip 3, as well as an accumulator 4.

Housing 2 comprises a front end 2a, a rear end 2b, an upper end 2c, and a lower end 2d. Positioned on front end 2a is a tool holder 5, which holds a tool 6. Tool 6 is designed as a drill bit. Positioned in housing 2 are an electric motor 7, a drive shaft 8, a gear unit 9, and a control device 10. By means of electric motor 7, drive shaft 8 is driven via gear unit 9. Drive shaft 8 is in turn connected rigidly to tool 6 designed as a drill bit so that the rotational movement or the rotational torque is transferred from drive shaft 8 to drill bit 6. Drill bit 6 can thus be rotated either in direction R or in direction R′.

Control device 10 is equipped with electric motor 7 for controlling the rotational speed of electric motor 7 as well as for controlling the torque generated in electric motor 7. To do so, control device 10 is connected to electric motor 7 via lead A.

Grip 3 comprises a front end 3a, a rear end 3b, an upper end 3c, and a lower end 3d. Upper end 3c of grip 3 is attached to lower end 3d as well as in the vicinity of rear end 2b of housing 2. A switch 11 is provided on front end 3a of grip 3. Switch 11 is designed in the form of a potentiometer and connected via a connecting cable B to control device 10. Machine tool 1 designed as a drill can be switched on and off with switch 11. In addition, the rotational speed of electric motor 7 as well as the torque generated in electric motor 7 can be varied in an infinitely variable manner with switch 11.

Accumulator 4 essentially comprises an accumulator housing 13, an accumulator control device 14, an input device 15 as well as a number of individual rechargeable storage elements for electrical energy. The storage elements may be described as secondary elements or secondary cells. The storage elements are not depicted in the drawings.

Accumulator housing 13 thereby comprises a front end 13a, a rear end 13b, an upper end 13c, and a lower end 13d. Positioned on upper end 13c of accumulator housing 13 is an interface 16 with which accumulator 4 can be connected to lower end 3d of grip 3 and thus to drill 1. Interface 16 thereby comprises multiple contacts by means of which information and electrical energy can be carried. The individual contacts are not depicted in the drawings. Accumulator 4 and in particular interface 16 are connected via a lead C to control device 10. In this way, control device 10 and accumulator control device 14 are connected to each other.

Accumulator control device 14 is positioned in accumulator housing 13 and is connected via lead 17 to interface 16. Accumulator control device 14 also comprises a non-depicted memory unit.

Input device 15 is positioned at front end 13a of accumulator housing 13 and connected to battery control device 14 via a lead 18. Input device 15 comprises a number of actuation elements as well as an indicator unit. The actuating elements are designed in the form of switches. The indicator unit is designed as a display. Neither the actuating elements nor the indicator unit are depicted in the drawings. As described in detail below, input device 15 serves to enter data and information (such as threshold values for a charging limit) into accumulator 4.

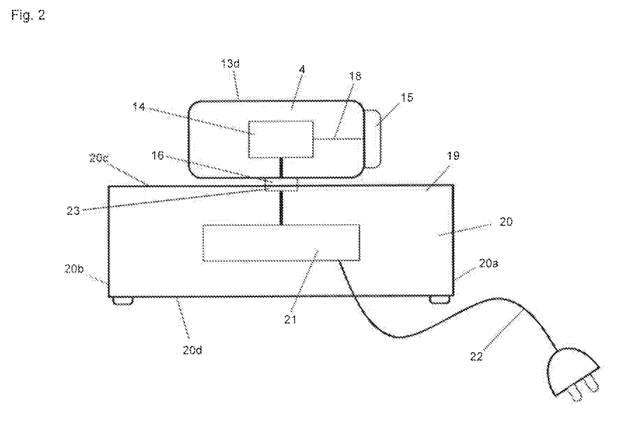

FIG. 2 depicts accumulator 4 in connection with a charging unit 19. Charging unit 19 essentially comprises a housing 20, a control device 21, and a power cable 22. Power cable 22 serves to connect charging device 19 to a (not depicted) mains current source (power outlet). Housing 20 comprises a front end 20a, a rear end 20b, an upper end 20c, and a lower end 20d. Arranged on upper end 20c of housing 20 of charging unit 19 is interface 23. Interface 23 contains multiple contacts, by means of which information and electrical energy may be carried. Interface 23 of charging device 19 is thereby designed in such a manner that the interface can be connected to interface 16 of accumulator 4. By means of the connection of both interfaces 23, 16, information and electrical energy can be exchanged between accumulator 4 and charging device 19. In particular, electrical energy may be carried from charging device 19 to accumulator 4, and information or data can be sent from accumulator 4 to charging device 19.

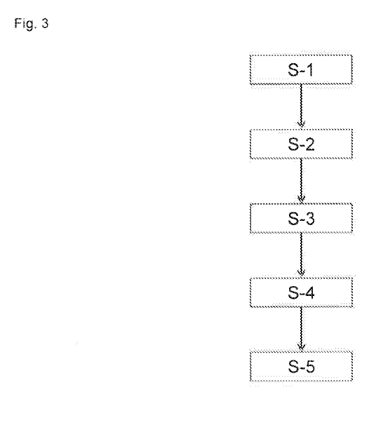

The method according to the invention for controlling an accumulator 4 is illustrated and described below by means of steps S-1 to S-5 of the sequence diagrams in FIGS. 3 to 6.

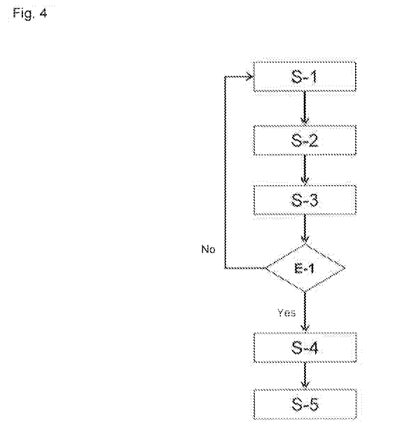

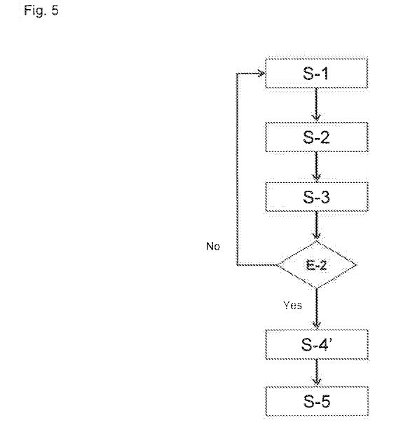

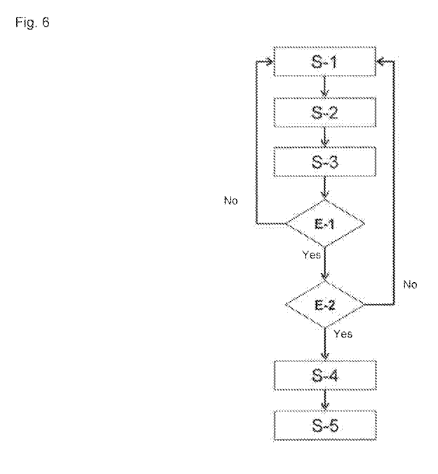

FIG. 3 thereby depicts a first embodiment of the method according to the invention; FIG. 4 thereby depicts a second embodiment of the method according to the invention; FIG. 5 thereby depicts a third embodiment of the method according to the invention; and FIG. 6 thereby depicts a fourth embodiment of the method according to the invention.

In step S-1 (cf. FIG. 3), accumulator 4 is connected to charging unit 19 in such a manner that information and electrical energy (electrical voltage) are exchanged via interfaces 23, 16 (cf. description above for FIG. 2). Accumulator 4 is electrically charged via charging unit 19 until a first charging state is reached. This first charging state may correspond for example to 90% of the electrical capacity of accumulator 4. The first charging state is stored in the memory unit of accumulator control device 14 of accumulator 4. However, it is also possible that the first charging state of battery 4 corresponds to a higher or lower value. The first charging state is generally the value of the electrical capacity that accumulator 4 has after a charging process (i.e., charging accumulator 4 on charging unit 19). It is hereby not necessary that the electrical capacity of accumulator 4 is 100% after the charging process; however, it may be the case.

In step S-2 (cf. FIG. 3), accumulator 4, as in the manner described above, is connected to machine tool 1 (cf. FIG. 1). The electrical capacity stored in accumulator 4 is hereby provided to machine tool 1 to operate electric motor 7. By machine tool 1 drawing on accumulator 4, the electrical capacity stored on accumulator 4 is continually reduced. In other words, the first charging state of accumulator 4 with an initial electrical capacity of 90% is reduced to a second charging state with an electrical capacity of only 30% for example. The difference between the first charging state and the second charging state is thus 60% (90%−30%=60%) of the electrical capacity. The second charging state is stored in the memory unit of accumulator control device 14 of accumulator 4. However, it is also possible that the second charging state has a higher or lower value for the electrical capacity. The value of the electrical capacity for the second charging state is oriented to how much of the electrical capacity (first charging state) stored on accumulator 4 is initially used by a user to operate machine tool 1.

In third step S-3 (cf. FIG. 3), the difference described above between the first charging state and the second charging state is stored in the form of a difference value (90%−30%=60% of the electrical capacity of accumulator 4) in the memory unit of control device 14 of accumulator 4. It is also possible that this difference value is assigned a tolerance value of +/−5%, for example. The tolerance value may also be higher or lower.

In fourth step S-4 (cf. FIG. 3), a third charging state is specified for accumulator 4. The third charging state corresponds to the previously determined difference value between a first charging process and a second charging process (90%−30%=60%), and is the maximum permissible value for the electrical capacity for a subsequent charging process for accumulator 4. In other words, accumulator 4 can no longer be charged in a subsequent charging process on charging device 19 until reaching the first charging state (i.e., 90% of the electrical capacity) or the maximum capacity (=100%), but can only be charged until reaching the third charging state (i.e., 60% of the electrical capacity).

In fifth step S-5 (cf. FIG. 3), accumulator 4 is charged until reaching the third charging state (60% of the electrical capacity of accumulator 4). To this end, accumulator 4 is connected to charging device 19 (cf. FIG. 2).

By specifying a third charging state (60%), which is considered a maximum upper limit for a subsequent charging process, and which lies below the maximum charging capacity of accumulator 4 (100%), accumulator 4 can be protected from premature aging as well as damage due to repeated charging until reaching a maximum charge, since the accumulator is no longer charged to 100% of the electrical capacity). Since the user typically also does not use the theoretically possible 100% of the electrical capacity of accumulator 4, this is also not problematic when using accumulator 4. If the demand of the user were to reach the level of the electrical capacity to be used, the third charging state can also be increased and a higher electrical capacity can thereby be provided.

According to a second embodiment of the method according to the invention, it is provided that an average value of multiple charging processes or charging cycles (e.g., three charging process or charging cycles) is used as a basis for setting the difference value between a first charging state and a second charging state. This means that a history is generated from a number of usage and also charging cycles. A charging cycle refers to one charging as well as one discharging of accumulator 4. To set the third charging state, this history is taken into account. To this end and for the second embodiment of the method according to the invention pursuant to step S-3, the average value of three charging processes is determined to set the difference value in event E-1 (cf. FIG. 4). In event E-1, a decision is made whether three charging processes have already occurred or not. If three charging processes have occurred, the method continues with step S-4. If three charging process have not yet occurred, the method continues with step S-1. According to another embodiment of the method according to the invention, more or fewer charging processes can be used as a basis. By means of the determined average value for the difference value, the quantity of the electrical capacity that is used by the (not depicted) user from accumulator 4 can be better determined and a continuous changing of the third charging state (i.e., after every use) can be avoided.

Pursuant to a third embodiment of the method according to the invention, it is provided that for the third charging state, a predetermined (capacity) value is set, if the second charging state falls below a predetermined (capacity) value. This means that if accumulator 4 is discharged so far that the second charging state corresponds to only 20% of the electrical capacity for example, the third charging state is set to 95% of the electrical capacity for example. To do so, in event E-2, which follows step S-3, one determines whether the predetermined (capacity) value for the second charging state is fallen short of (cf. FIG. 5). If this predetermined (capacity) value is fallen short of, the method is continued with step S-4′ and a predetermined (capacity) value is set for the third charging state. However, if this predetermined (capacity) value was not fallen short of, the method continues with step S-1.

Pursuant to a fourth embodiment of the method according to the invention, it is provided that events E-1 and E-2 described above are subsequently carried out after step S-3 (cf. FIG. 6).

1.-6. (canceled)

7. A method for controlling an accumulator, comprising the steps of:
determining a difference value between a first charging state of the accumulator and a second charging state of the accumulator, wherein the first charging state corresponds to a charging state of the accumulator after a charging process has ended and the second charging state has a lower charging state value than the first charging state;
specifying a third charging state, wherein the third charging state corresponds to the difference value and is lower than a maximum charging state value of the accumulator; and
charging the accumulator until reaching the third charging state.

8. The method according to claim 7, wherein the specifying of the third charging state occurs after a predetermined number of charging processes of the accumulator and wherein the difference value of the third charging state corresponds to an average difference value of the predetermined number of charging processes.

9. The method according to claim 7, wherein the third charging state is a predetermined first threshold value if the second charging state falls below a predetermined second threshold value.

10. The method according to claim 7, wherein the specifying of the third charging state occurs by an input device positioned on the accumulator.

11. The method according to claim 7, wherein the first charging state, the second charging state, and the third charging state correspond to a capacity, a charging voltage, or a charging current.

12. An accumulator which performs the method according to claim 7.
